(19) United States
(12) Patent Application Publication
(10) Pub. No.: US 2020/0081304 A1
(43) Pub. Date: Mar. 12, 2020

(54) STRUCTURE OF PREVENTING ELECTROSTATIC BREAKDOWN OF A PANEL PERIPHERAL WIRING

(71) Applicant: Shenzhen China Star Optoelectronics Semiconductor Display Technology Co., Ltd, Shenzhen, Guangdong (CN)

(72) Inventor: Tianhong WANG, Shenzhen, Guangdong (CN)

(21) Appl. No.: 15/744,808

(22) PCT Filed: Dec. 14, 2017
(86) PCT No.: PCT/CN2017/116279

§ 371 Date: Jan. 14, 2018

(30) Foreign Application Priority Data
Nov. 7, 2017 (CN) 201711086287.4

(51) Int. Cl. G02F 1/1362; H01L 27/12; G02F 1/1368

(52) U.S. Cl. CPC G02F 1/136204; G02F 1/136286; G02F 1/1368; H01L 27/124

(57) ABSTRACT

A structure for preventing electrostatic damage to a peripheral wiring of a panel, comprising a first metal wiring (10) made of a first metal layer as a peripheral wiring, and a plurality of second metal wirings (20) made of a second metal layer, wherein the plural second metal wirings are opposite to the first metal wiring from top to bottom and arranged along a wiring direction of the first metal wiring; a dielectric layer (30) provided between the second metal wirings and the first metal wiring, wherein two adjacent second metal wirings are connected by the dielectric layer; a plurality of capacitors (C1, C2, C3) formed by the second metal wirings and the corresponding first metal wiring acting as opposite electrodes, including at least two capacitors whose capacitance values are not equal. The structure for preventing electrostatic damage to the peripheral wiring of a panel is made by adding a layer of metal wire on an existing peripheral wiring as an ESD protection circuit to achieve an antistatic effect, and is capable of shortening process inspection time and reducing production cost.

### RELATED APPLICATIONS

The present application is a National Phase of International Application Number PCT/CN2017/116279, filed on Dec. 14, 2017, and claims the priority of China Application 201711086287.4, filed on Nov. 7, 2017

### FIELD OF THE DISCLOSURE

The disclosure relates to a liquid crystal display technical field, and more particularly to a structure of preventing electrostatic breakdown of a panel peripheral wiring.

### BACKGROUND

With the development of display technology, the flat panel device, such as Liquid Crystal Display (LCD) possesses advantages of high image quality, power saving, thin body and wide application scope. Thus, it has been widely applied in various consumer electrical products, such as mobile phone, television, personal digital assistant, digital camera, notebook, laptop, and becomes the major display device.

In the active matrix liquid crystal display, each pixel has a thin film transistor (TFT). The gate thereof is connected to the horizontal scanning line, the drain thereof is connected to the data line in the vertical direction, and the source thereof is connected to the pixel electrode. Applying enough voltage on the horizontal scanning line will turn on all TFTs on this line. At this time, the pixel electrodes on the horizontal scanning line will be connected with the data lines in the vertical direction, then write the display signal on the data lines into pixel, and control various liquid crystal transmittances to control the color.

In the LCD manufacturing process, due to considering the yield, the process will need to test the product in a specific part to find the problems in order to repair to improve product yield. If the product needs to be tested, the GOA circuit of the panel and the active area (AA) need to be power on, so the signal pad needs to be set around the peripheral wiring of the panel so that the probe could conduct to the signal pad. However, ESD may occur on the peripheral wiring of the panel, and the automated optical inspection (AOI) machine may not be able to scan the peripheral wiring of the panel when scanning the panel, so it must be photographed by a fixed-point or manual inspection. Due to the ESD location is random, it is very difficult to effectively detect ESD in a short period of time or missing ESD, and lead to loss of production.

AS shown in FIG. 1, is a schematic diagram of a peripheral wiring of a conventional liquid crystal display panel. Wherein, a HVA pad 1 enters the interior of a panel 5 from a peripheral wiring 3 close to the HVA pad 1, another HVA pad 2 is from the lower left side around a peripheral wiring 4 to the upper right corner into the interior of the panel 5, in order to provide a test signal to the panel 5. Currently, the peripheral wirings 3, 4 are usually only formed by the first metal layer (M1) and with no ESD protection circuit. Therefore, the peripheral wirings 3, 4 tend to accumulate static electricity during the manufacturing process, and then ESD is prone to occur at the line-crossing area.

### SUMMARY

A technical problem to be solved by the disclosure is to provide a structure of preventing electrostatic breakdown of a panel peripheral wiring, so ESD could be avoided occurring via providing the ESD protection circuit.

To achieve the above object, according to one aspect, the embodiment of the disclosure provides a structure of preventing electrostatic breakdown of a panel peripheral wiring, including:

a first metal wiring, as a peripheral wiring manufactured by a first metal layer; and

a plurality of second metal wirings, manufactured by a second metallayer;

wherein the second metal wirings are disposed opposite to the first metal wiring and arranged along a wiring direction of the first metal wiring, a dielectric layer is disposed between the first metal wiring and the second metal wirings and two adjacent second metal wirings connect to each other via the dielectric layer, a plurality of capacitors formed between the first metal wiring and the second metal wirings, and the capacitors include two capacitors with different capacitance values.

In an embodiment, wherein the first metal layer is a gate metal layer.

In an embodiment, wherein the second metal layer is a source/drain metal layer.

In an embodiment, wherein a width of each of the second metal wirings is the same, and at least two of the second metal wirings have different lengths.

In an embodiment, wherein lengths of the second metal wirings increase sequentially.

In an embodiment, wherein the second metal wirings include three second metal wirings.

In an embodiment, wherein the dielectric layer includes amorphous silicon.

In an embodiment, wherein the first metal wiring is covered by an insulating layer.

In an embodiment, wherein the peripheral wiring is a peripheral wiring of an active LCD.

According to another aspect, the embodiment of the disclosure provides a structure of preventing electrostatic breakdown of a panel peripheral wiring, including:

a first metal wiring, as a peripheral wiring manufactured by a first metal layer; and

a plurality of second metal wirings, manufactured by a second metal layer;

wherein the second metal wirings are disposed opposite to the first metal wiring and arranged along a wiring direction of the first metal wiring, a dielectric layer is disposed between the first metal wiring and the second metal wirings and two adjacent second metal wirings connect to each other via the dielectric layer, a plurality of capacitors formed between the first metal wiring and the second metal wirings, and the capacitors include two capacitors with different capacitance values;

wherein the first metal layer is a gate metal layer;

wherein the first metal layer is a gate metal layer;

wherein a width of each of the second metal wirings is the same, and at least two of the second metal wirings have different lengths;

wherein lengths of the second metal wirings increase sequentially.

By practice of the disclosure. The structure of preventing electrostatic breakdown of a panel peripheral wiring provided by the embodiments of the disclosure could add a metal wiring as the ESD protection circuit, so the anti-static effect could be achieved, and the testing time of process and the manufacturing cost could be decreased.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a schematic diagram of a peripheral wiring of a conventional liquid crystal display panel;

FIG. 2 is a schematic diagram of a principle a structure of preventing electrostatic breakdown of a panel peripheral wiring according to an embodiment of the disclosure; and

FIG. 3 is a schematic diagram of FIG. 2 after finishing an array process.

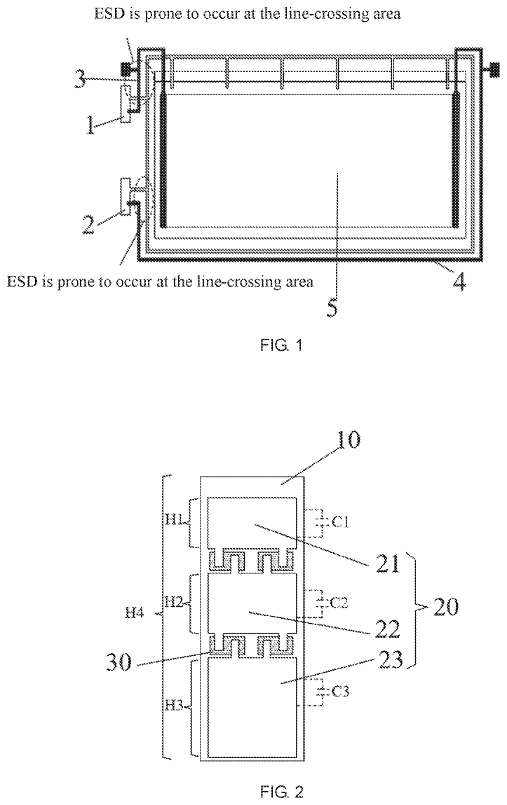

### DETAILED DESCRIPTION OF PREFERRED EMBODIMENTS

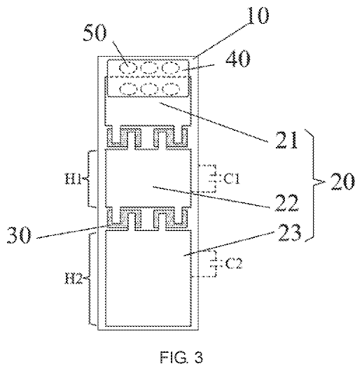

As shown in FIG. 2, is a schematic diagram of a principle a structure of preventing electrostatic breakdown of a panel peripheral wiring according to an embodiment of the disclosure. To show the structure clearly, FIG. 2 shows the structure before the passivation (PV) process is performed, that is, the passivation layer and the subsequent structure are removed. A structure of preventing electrostatic breakdown of a panel peripheral wiring provided by the disclosure includes: a first metal wiring 10 as a peripheral wiring manufactured by a first metal layer, and a plurality of second metal wirings 20 manufactured by a second metal layer. In a general panel, the first metal layer may be formed by a gate metal layer and the second metal layer may be formed by a source/drain metal layer. That is, the first metal wiring 10 and the second metal wirings 20 could be manufactured by the existing process. The second metal wirings 20 are disposed opposite to the first metal wiring 10 and arranged along a wiring direction of the first metal wiring 10, and a dielectric layer 30 is disposed between the first metal wiring 10 and the second metal wirings 20 and two adjacent second metal wirings 20 connect to each other via the dielectric layer 30, so a TFT structure is formed by the first metal wiring 10, the dielectric layer 30 and the two adjacent second metal wirings 20. The dielectric layer 30 may include amorphous silicon. According to the general display panel structure, the first metal wiring 10 could be covered by an insulating layer, and a plurality of capacitors formed between the first metal wiring 10 and the second metal wirings 20, wherein the capacitors include two capacitors with different capacitance values. The two capacitors with different capacitance values could be adjacent to each other or not. In this embodiment, the second metal wirings 20 include three second metal wirings 21, 22, 23, wherein a capacitor C1 is formed between the second metal wiring 21 and the first metal wiring 10, a capacitor C2 is formed between the second metal wiring 22 and the first metal wiring 10, a capacitor C3 is formed between the second metal wiring 23 and the first metal wiring 10, and at least two of the capacitors C1, C2, C3 with different capacitance values.

Generally, in order to simplify the design, the width of the first metal wiring 10 and the second metal wiring 20 may be set to be constant. In this case, the second metal wiring 20 and the first metal wiring 10 opposite to each other are formed as the opposite electrodes of the capacitors C1, C2, C3 the capacitance value could be controlled by setting the length of each of the second metal wirings 20. As shown in FIG. 2, the lengths H1, H2, H3 of the second metal wirings 20 increase sequentially.

The structure of preventing electrostatic breakdown of a panel peripheral wiring is suitable for all the active LCD products. The peripheral wiring is the peripheral wiring of the GOA circuit and the active area of the active LCD.

The structure of preventing electrostatic breakdown of a panel peripheral wiring includes self-capacitance type ESD. As shown in FIGS. 2, H1, H2, H3 and H4 represent the lengths of the metal wirings, H1<H2<H3<H4. C1, C2 and C3 represent the capacitors are formed between the first metal layer and the second metal layer, because of the difference of the lengths of the metal wirings, C1<C2<C3. After finishing the second metal layer process, i.e. the source/drain process, ESD of the capacitors could work. When the long metal wiring of the first metal layer accumulates a larger static electricity voltage V4, the second metal layer accumulate smaller static electricity voltages V1, V2, V3, so the TFT between V1 and V2 will turn on and discharge, and a large voltage difference is formed between the larger static electricity voltage V4 of the first metal layer and V1, V2, V3 to form an electrostatic discharge path between the first metal layer (i.e. the peripheral wiring) and the second metal layer, in order to avoid ESD occurring at the HAV pad line-crossing area or other line-crossing area.

As shown in FIG. 3, is a schematic diagram of FIG. 2 after finishing an array process. After finishing the array process, the upper substrate and the lower substrate of the display panel adhere to each other via a conductive sealant 40, so the second metal wirings 20 located at the edge and the first wiring 10 opposite to the second metal wirings 20 will electrically connect to each other via the golden balls 50 in the conductive sealant 40, but the ESD protection function formed between the first wiring 10 and the second metal wirings 20 is not affected. The principle of operation is the same as that shown in FIG. 2. Different capacitors C1 and C2 are formed by the second metal wirings 20 with different lengths H1 and H2 to generate the ESD protection function.

The structure of preventing electrostatic breakdown of a panel peripheral wiring of the disclosure only adds a metal layer on the original peripheral wiring without adding a new mask, and makes an electrostatic discharge path via the electrostatic accumulation difference between two metal wirings. In this disclosure, after the second metal layer is formed, a capacitor is formed by the second metal layer metal on the first metal layer and a TFT is combined, so the TFT could turn on by a voltage difference according to the different amount of accumulated static electricity to form an electrostatic discharge path and the ESD protection function could be achieved.

In summary, the structure of preventing electrostatic breakdown of a panel peripheral wiring provided by the embodiments of the disclosure could add a metal wiring as the ESD protection circuit, so the anti-static effect could be achieved, and the testing time of process and the manufacturing cost could be decreased.

The foregoing contents are detailed description of the disclosure in conjunction with specific preferred embodiments and concrete embodiments of the disclosure are not limited to these descriptions. For the person skilled in the art of the disclosure, without departing from the concept of the disclosure, simple deductions or substitutions can be made and should be included in the protection scope of the application.

What is claimed is:

1. A structure of preventing electrostatic breakdown of a panel peripheral wiring, comprising:
a first metal wiring, as a peripheral wiring manufactured by a first metal layer; and
a plurality of second metal wirings, manufactured by a second metal layer;
wherein the second metal wirings are disposed opposite to the first metal wiring and arranged along a wiring direction of the first metal wiring, a dielectric layer is disposed between the first metal wiring and the second metal wirings and two adjacent second metal wirings connect to each other via the dielectric layer, a plurality of capacitors formed between the first metal wiring and the second metal wirings, and the capacitors include two capacitors with different capacitance values.

2. The structure of preventing electrostatic breakdown of a panel peripheral wiring according to claim 1, wherein the first metal layer is a gate metal layer.

3. The structure of preventing electrostatic breakdown of a panel peripheral wiring according to claim 1, wherein the second metal layer is a source/drain metal layer.

4. The structure of preventing electrostatic breakdown of a panel peripheral wiring according to claim 1, wherein a width of each of the second metal wirings is the same, and at least two of the second metal wirings have different lengths.

5. The structure of preventing electrostatic breakdown of a panel peripheral wiring according to claim 4, wherein lengths of the second metal wirings increase sequentially.

6. The structure of preventing electrostatic breakdown of a panel peripheral wiring according to claim 5, wherein the second metal wirings include three second metal wirings.

7. The structure of preventing electrostatic breakdown of a panel peripheral wiring according to claim 1, wherein the dielectric layer includes amorphous silicon.

8. The structure of preventing electrostatic breakdown of a panel peripheral wiring according to claim 1, wherein the first metal wiring is covered by an insulating layer.

9. The structure of preventing electrostatic breakdown of a panel peripheral wiring according to claim 1, wherein the peripheral wiring is a peripheral wiring of an active LCD.

10. A structure of preventing electrostatic breakdown of a panel peripheral wiring, comprising:
a first metal wiring, as a peripheral wiring manufactured by a first metal layer; and
a plurality of second metal wirings, manufactured by a second metal layer;
wherein the second metal wirings are disposed opposite to the first metal wiring and arranged along a wiring direction of the first metal wiring, a dielectric layer is disposed between the first metal wiring and the second metal wirings and two adjacent second metal wirings connect to each other via the dielectric layer, a plurality of capacitors formed between the first metal wiring and the second metal wirings, and the capacitors include two capacitors with different capacitance values;
wherein the first metal layer is a gate metal layer;
wherein the first metal layer is a gate metal layer;
wherein a width of each of the second metal wirings is the same, and at least two of the second metal wirings have different lengths;
wherein lengths of the second metal wirings increase sequentially.

11. The structure of preventing electrostatic breakdown of a panel peripheral wiring according to claim 10, wherein the second metal wirings include three second metal wirings.

12. The structure of preventing electrostatic breakdown of a panel peripheral wiring according to claim 10, wherein the dielectric layer includes amorphous silicon.

13. The structure of preventing electrostatic breakdown of a panel peripheral wiring according to claim 10, wherein the first metal wiring is covered by an insulating layer.

14. The structure of preventing electrostatic breakdown of a panel peripheral wiring according to claim 10, wherein the peripheral wiring is a peripheral wiring of an active LCD.
